(19) United States
(12) Patent Application Publication
(10) Pub. No.: US 2007/0007576 A1
(43) Pub. Date: Jan. 11, 2007

(54) Multi-bit storageable non-volatile memory device

(75) Inventors: Shi-Eun Kim, Seoul (KR); Seung-Jae Baik, Seoul (KR); Zong-Liang Huo, Suwon-si (KR); In-Seok Yeo, Seoul (KR); Seung-Hyun Lim, Yongin-si (KR); Jeong-Hee Han, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/482,526

(22) Filed: Jul. 7, 2006

(30) Foreign Application Priority Data
Jul. 7, 2005 (KR) 2005-61356
Jan. 18, 2006 (KR) 2006-05532

(51) Int. Cl. H01L 29/76

(52) U.S. Cl. 257/314

(57) ABSTRACT

A non-volatile memory device includes a channel region defined between a source region and a drain region, a charge storage film disposed on the channel region to store a charge, and a tunnel insulating film interposed between the channel region and the charge storage film to tunnel the charge, the tunnel insulating film having a quantum confinement film.

### CROSS-REFERENCE TO RELATED APPLICATIONS

This application claims priority to Korean patent application No. 2005-61356 filed on Jul. 7, 2005 and Korean patent application No. 2006-05532 filed on Jan. 18, 2006, the contents of both applications are incorporated by reference in their entireties herein.

### BACKGROUND OF THE INVENTION

1. Technical Field

The present disclosure relates to a multi-bit storageable non-volatile memory device and a method of fabricating the same, and more particularly, to a multi-bit storageable non-volatile memory device storing a plurality of data bits in one memory cell and a method of fabricating the same.

2. Discussion of the Related Art

A memory device having multi-level cells can store a plurality of data bits either by assigning data bits to a plurality of storage regions in a memory cell, or by dividing a threshold voltage of the memory cell into a plurality of intervals to assign data bits to the plurality of intervals.

Charge trapping films, which are adjacent to each of a source region and a drain region of a transistor, can be used as data storage regions. For example, two bits can be stored with one bit in each charge trapping film. However, it is difficult to identify one bit from the other since the storage regions are so close to each other, with channel length at around 100 nm.

A non-volatile memory device can divide a threshold voltage of the memory cell into a plurality of intervals and assign the data bit to each threshold voltage level.

FIG. 1 is a sectional view illustrating a conventional silicon-oxide-nitride-oxide-silicon (SONOS) memory cell. FIG. 2 is a graph illustrating a write voltage in relation to a threshold voltage of the conventional SONOS memory cell.

Referring to FIG. 1, the SONOS memory cell of a non-volatile memory device includes a source region 12s and a drain region 12d formed on a semiconductor substrate 10, and a charge storage film 20 comprising a plurality of films formed on a channel region between the source region 12s and the drain region 12d. A gate electrode 22 is formed on the charge storage film 20 comprising the plurality of films.

The charge storage film 20 includes a sequentially stacked tunnel insulating film 14, a charge trapping film 16, and a blocking insulating film 18. The tunnel insulating film 14 and the blocking insulating film 18 may comprise a silicon-oxide film, and the charge trapping film 16 may comprise a silicon-nitride film having a dielectric constant and a trap density higher than those of the silicon-oxide film.

Referring to FIG. 2, the write voltage increases in proportion to the threshold voltage in a conventional non-volatile memory device, and the threshold voltage is linearly proportional to the write voltage in a constant interval. The quantity of charge that tunnels through the tunnel insulating film increases when a positive write voltage applied to a gate electrode increases. Therefore, the threshold voltage increases due to electrons stored in the charge trapping film 16 and holes separated from the charge trapping film 16.

To store a plurality of data bits, the threshold voltage can be divided into a predetermined interval, and data bits of ‘00’, ‘01’, ‘10’, and ‘11’ are assigned to each predetermined interval. As illustrated in FIG. 2, in the conventional non-volatile memory device, the threshold voltage continuously increases in proportion to the write voltage in an operating voltage range. Accordingly, although an identical write voltage is applied, there may be a difference in voltage distributed to the tunnel insulating film 14, due to a thickness, a channel length, and a width of the tunnel insulating film 14, the charge trapping film 16 and the blocking insulating film 18. Therefore, as a distribution of the threshold voltage in the written memory cell increases, an identification of data becomes difficult. Thus, a verify window Vp of data becomes small.

A need therefore exists for a non-volatile memory device with reduced influence of the distribution of cell characteristics on a threshold voltage. There is also a need for a non-volatile memory device including a wide verify window and a high distribution margin of a write voltage.

### SUMMARY OF THE INVENTION

A non-volatile memory device according to an examplary embodiment of the present invention may include a tunnel insulating film with a quantum confinement film.

According to an examplary embodiment of the present invention, a non-volatile memory device comprises a channel region defined between a source region and a drain region, a charge storage film disposed on the channel region to store a charge, and a tunnel insulating film interposed between the channel region and the charge storage film to tunnel the charge, the tunnel insulating film having a quantum confinement film.

According to an examplary embodiment of the present invention, a non-volatile memory device comprises a source region and a drain region formed on a semiconductor substrate, a tunnel insulating film formed on a channel region between the source region and the drain region, a charge trap insulating film formed on the tunnel insulating film, a blocking insulating film formed on the charge trap insulating film, and a gate electrode formed on the blocking insulating film, wherein the tunnel insulating film includes a bottom tunnel insulating film, a quantum confinement film, and a top tunnel insulating film.

According to an examplary embodiment of the present invention, a non-volatile memory device comprises a source region and a drain region formed on a semiconductor substrate, a tunnel insulating film formed on a channel region between the source region and the drain region, a floating gate formed on the tunnel insulating film, a gate interlayer dielectric film formed on the floating gate, and a control gate electrode formed on the gate interlayer dielectric film, wherein the tunnel insulating film includes a bottom tunnel insulating film, a quantum confinement film, and a top tunnel insulating film.

### BRIEF DESCRIPTION OF THE DRAWINGS

Examplary embodiments of the present disclosure can be understood in detail from the following description taken in conjunction with the accompanying drawings of which:

FIG. 1 is a cross-sectional view illustrating a conventional SONOS memory cell;

FIG. 2 is a graph illustrating a write voltage in relation to a threshold voltage of a conventional SONOS memory cell;

FIG. 3 is a cross-sectional view illustrating a non-volatile memory device according to an examplary embodiment of the present invention;

FIG. 4 is an energy band diagram of a non-volatile memory device according to an examplary embodiment of the present invention;

FIG. 5 is a graph illustrating a write voltage in relation to a tunneling current of a non-volatile memory device according to an examplary embodiment of the present invention;

FIG. 6 is a graph illustrating a write voltage in relation to a threshold voltage of a non-volatile memory device according to an examplary embodiment of the present invention;

FIG. 7 is a graph illustrating a write voltage in relation to a threshold voltage and distribution of the threshold voltage of a non-volatile memory device according to an examplary embodiment of the present invention;

FIG. 8 is an energy band diagram of a non-volatile memory device according to an examplary embodiment of the present invention;

FIG. 9 is a cross-sectional view of a non-volatile memory device according to an examplary embodiment of the present invention;

FIG. 10 is a graph illustrating a write time in relation to a threshold voltage according to a conventional non-volatile memory device;

FIG. 11 is a graph illustrating a write voltage in relation to a threshold voltage according to a conventional non-volatile memory device;

FIG. 12 is a graph illustrating a write time in relation to a threshold voltage according to an examplary embodiment of the present invention;

FIG. 13 is a graph illustrating a write voltage in relation to a threshold voltage according to an examplary embodiment of the present invention;

FIG. 14 is a cross-sectional view of a non-volatile memory device according to an examplary embodiment of the present invention;

FIG. 15 is a cross-sectional view of a non-volatile memory device according to an examplary embodiment of the present invention;

FIG. 16 is a cross-sectional view of a non-volatile memory device according to an examplary embodiment of the present invention;

FIG. 17 is a cross-sectional view of a non-volatile memory device according to an examplary embodiment of the present invention; and

FIG. 18 is a cross-sectional view of an examplary embodiment of the present invention.

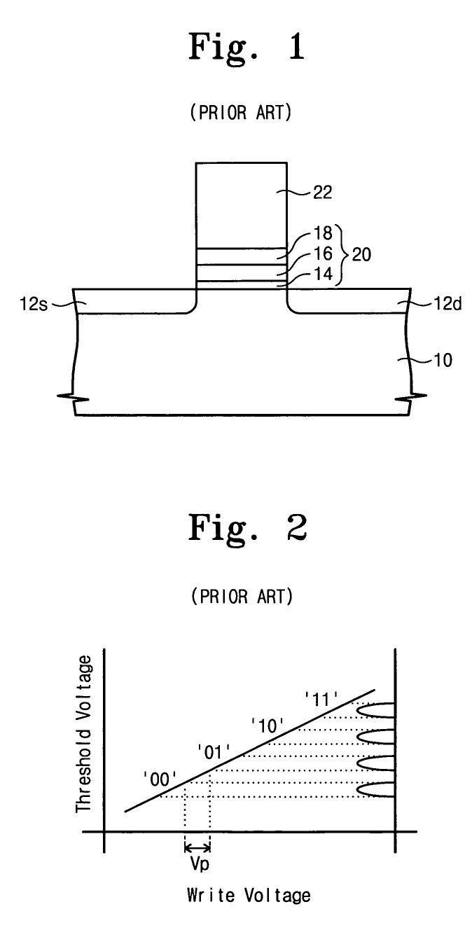

### DESCRIPTION OF EXAMPLARY EMBODIMENTS

Examplary embodiments of the present invention will be described in detail with reference to the accompanying drawings. The present invention may, however, be embodied in many different forms and should not be construed as limited to the embodiments set forth herein.

FIG. 3 is a cross-sectional view illustrating a non-volatile memory device according to an examplary embodiment of the present invention.

Referring to FIG. 3, a source region 52s and a drain region 52d are formed on a semiconductor substrate 50. A charge storage film 60 comprising a plurality of films is formed on a channel region between the source region 52s and the drain region 52d. A gate electrode 62 is formed on the charge storage film 60. The charge storage film 60 includes a tunnel insulating film 54, a charge trap insulating film 56, and a blocking insulating film 58. These films are preferably sequentially stacked. The tunnel insulating film 54 includes a quantum confinement film 66 having a quantum confinement effect. The quantum confinement film 66 is interposed between a bottom tunnel insulating film 64 and a top tunnel insulating film 68. Tunneling of a charge occurs in the tunnel insulating film 54 during a write operation or an erase operation.

The quantum confinement film 66 may be made of a material having a potential barrier lower than the bottom tunnel insulating film 64 and the top tunnel insulating film 68.

Quantum confinement effect occurs in a particle or a film in a nano scale. A band gap can be increased and discontinued when the particle or the film is reduced to the nano scale. A nano crystal film in which nano particles are distributed does not have a step-like tunneling effect but has a general tunneling effect. The quantum confinement effect does not occur in the nano crystal film even if each particle generates the quantum confinement effect because the degree of distribution of a particle size is large in the nano crystal film.

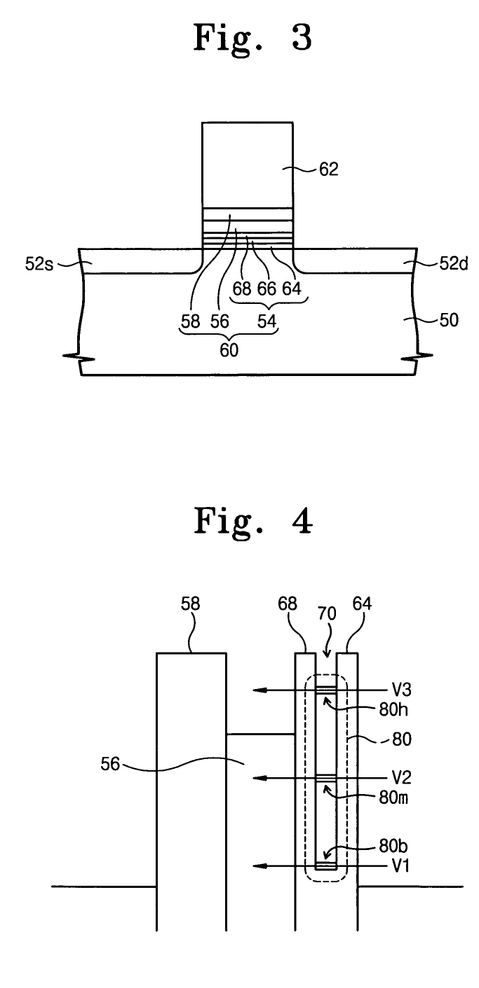

FIG. 4 is an energy band diagram of a non-volatile memory device according to an examplary embodiment of the present invention.

Referring to FIG. 4, the tunnel insulating film 54 includes a bottom tunnel insulating film 64 and a top tunnel insulating film 68 of a high potential barrier and a quantum confinement film 66 of a low potential barrier. The quantum confinement film 66 forms a low potential well 70 between high potential barriers. When the quantum confinement film 66 is sufficiently thin, a continuous conduction band can be divided into a plurality of conduction bands 80. A charge that tunnels the bottom tunnel insulating film 64 and the top tunnel insulating film 68 passes through the plurality of conduction bands 80 and moves toward the charge trap insulating film 56 according to a voltage applied to the tunnel insulating film 54, wherein a tunneling current generates a discontinuous peak because an energy state of a conduction band is selected according to the applied voltage. As an example, when a first voltage V1 is applied, the charge moves through a bottom conduction band 80b. When a relatively-high second voltage V2 is applied, the charge moves through the bottom conduction band 80b and a middle conduction band 80m. When a third voltage V3 is applied, the charge moves through the bottom conduction band 80b, the middle conduction band 80m, and a top conduction band 80h. Therefore, the tunneling current increases in a step shape with a stable interval and a rising interval when the applied voltage is increased.

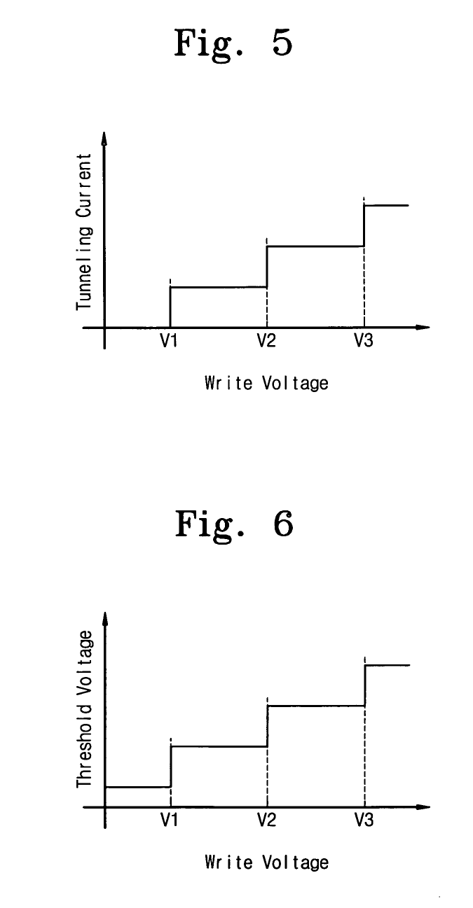

FIG. 5 is a graph illustrating a write voltage in relation to a tunneling current of a non-volatile memory device according to an examplary embodiment of the present invention. FIG. 6 is a graph illustrating the write voltage in relation to a threshold voltage of a non-volatile memory device according to an examplary embodiment of the present invention.

Referring to FIGS. 4, 5 and 6, a current through the quantum confinement film 66 passes through the tunnel insulating film 54 and induces a discontinuous increase of charge between the semiconductor substrate 50 and the charge trap insulating film 56. Thus, the write voltage in relation to the tunneling current can be a step form.

As illustrated in FIG. 6, when the write voltage is applied with a same interval, the threshold voltage increases in a step shape according to an increase of the voltage. That is, when the interval is divided into a first voltage below interval, a first voltage V1-second voltage V2 interval, a second voltage V2-third voltage V3 interval, and a third voltage V3 above interval, the threshold voltage does not change even if a distribution of the write voltage occurs in each interval. Accordingly, due to the characteristic distribution of a cell transistor, the threshold voltage does not change even if the distribution of a voltage applied to the tunnel insulating film 54 occurs.

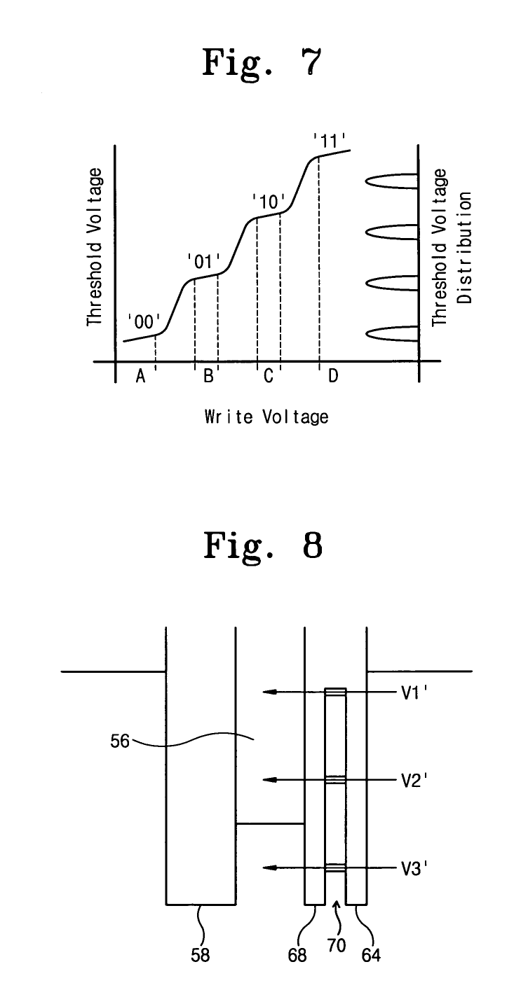

FIG. 7 is a graph illustrating the write voltage in relation to the threshold voltage and a distribution of the threshold voltage of a non-volatile memory device according to an examplary embodiment of the present invention.

Referring to FIG. 7, data bits of ‘00’, ‘01’, ‘10’, and ‘11’ are assigned to each of stable intervals (A, B, C, D) of a step-shaped threshold voltage curve in relation to the write voltage. Accordingly, the distribution of the threshold voltage occurs in each data state. However, compared to a conventional non-volatile memory device, the interval between the data bits is wider and the distribution of the threshold voltage is substantially small.

FIG. 8 is an energy band diagram of a non-volatile memory device according to an examplary embodiment of the present invention.

Referring to FIG. 8, in a non-volatile memory device, writing and erasing can be performed using a tunneling of electrons and a tunneling of holes through a potential well and a quantum confinement effect of a valence band. As illustrated in FIG. 8, a potential well of a low potential barrier with respect to holes is generated between the bottom tunnel insulating film 64 and the top tunnel insulating film 68 in the valence band. Holes can be injected between the gate electrode 62 and the channel region through a divided conduction band of the quantum confinement film 66, to which voltages (V1′, V2′, and V3′) are applied. In a silicon oxide film and a silicon nitride film, a linear function of the conduction band is 1.1 eV. A linear function of the valence band is 2.6 eV. A potential well of the valence band is deeper compared to the conduction band. Accordingly, the writing and erasing of the non-volatile memory device may be more effective when using the tunneling of holes instead of the tunneling of electrons.

FIG. 9 is a cross-sectional view of a non-volatile memory device according to an examplary embodiment of the present invention.

Examplary embodiments of the present invention can be applied to a charge trap type non-volatile memory device and a floating gate type non-volatile memory device. Referring to FIG. 9, the non-volatile memory device includes a source region 102s and a drain region 102d formed on a substrate 100, a bottom tunnel insulating film 114 on a channel region between the source region 102s and the drain region 102d, and a tunnel insulating film 104 comprising a quantum confinement film 116 and a top tunnel insulating film 118.

A floating gate 106, a gate interlayer dielectric film 108, and a control gate electrode 110 are stacked on the tunnel insulating film 104. The gate interlayer dielectric film 108 may comprise, for example, a silicon oxide film—a silicon nitride film—a silicone oxide film. According to an examplary embodiment of the present invention, the gate interlayer dielectric film 108 may comprise a single layer insulating film having a high dielectric constant and a low leakage current.

Similar to the charge trap type non-volatile memory device, the current increases discontinuously in a step-form when the write voltage increases in the floating gate type non-volatile memory device. The change of the threshold voltage in the charge trap type non-volatile memory device and in the floating gate type non-volatile memory device is substantially similar to each other.

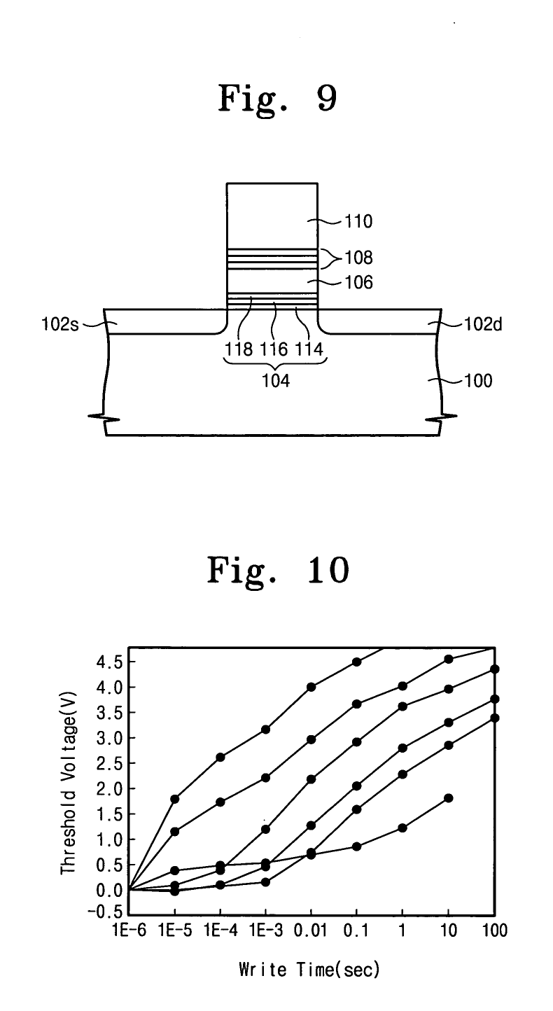

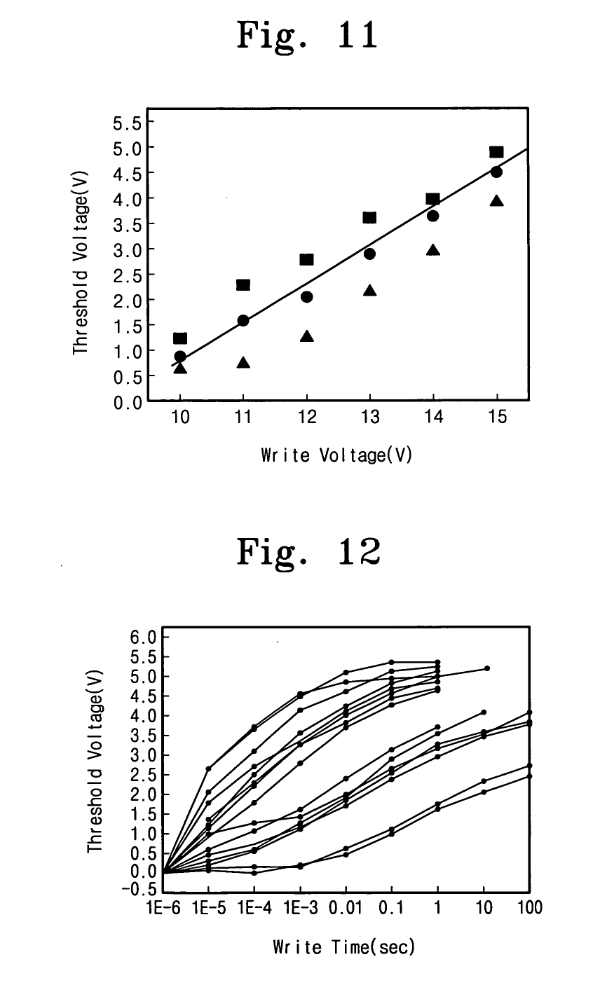

FIG. 10 is a graph illustrating the write time in relation to the threshold voltage according to the write voltage of a conventional non-volatile memory device. FIG. 11 is a graph illustrating the write voltage in relation to the threshold voltage according to the write time of a conventional non-volatile memory device. FIG. 12 is a graph illustrating the write time in relation to the threshold voltage according to the write voltage of a non-volatile memory device in an examplary embodiment of the present invention. FIG. 13 is a graph illustrating the write voltage in relation to the threshold voltage of a non-volatile memory device in an examplary embodiment the present invention. These graphs can be measured in a memory cell where a channel width and a channel length are about 0.16 μm and about 0.08 μm, respectively. The tunnel insulating film 14, the charge trap insulating film 16, and the blocking insulating film 18 of the conventional non-volatile memory device can be measured in a memory cell comprising a silicon oxide film of about 3 nm, a silicon nitride film of about 7 nm, and a silicon oxide film of about 7 nm. In a non-volatile memory device according to an examplary embodiment of the present invention, the bottom tunnel insulating film 64, the quantum confinement film 66, the top tunnel insulating film 68, the charge trap insulating film 56, and the blocking insulating film 58 are measured in a memory cell comprising a silicon oxide film of about 1.5 nm, an amorphous silicon film of about 1.5 nm, a silicon oxide film of about 3.2 nm, a silicon nitride film of about 7 nm, and a silicon oxide film of about 7 nm.

Referring to FIG. 10, when various write voltages are applied, the threshold voltage substantially increases in proportion to the write voltage as the write time elapses. In FIG. 11, the write time of 0.01 sec, 0.1 sec, and 1 sec are represented by a triangle, a circle, and a rectangle, respectively. As illustrated in FIG. 11, in the conventional non-volatile memory device, the threshold voltage increases substantially linearly when the write voltage increases.

Referring to FIG. 12, in a non-volatile memory device according to an examplary embodiment of the present invention, the threshold voltage can be varied according to the write voltage when the write time elapses. As illustrated in FIG. 13, the non-volatile memory device according to an examplary embodiment of the present invention generates a step-shaped threshold voltage curve having points P1 and P2, where the change of the threshold voltage substantially reduces, according to the increase of the write voltage.

Referring to FIG. 11, when the write time is 0.1 sec in a conventional non-volatile memory device, the threshold voltage increases from about 1.5 V to about 3.0 V (increase of about 1.5 V) when the write voltage increases from 11 V to 13 V. Referring to FIG. 13, when the write time is 0.1 sec in a non-volatile memory device according an examplary embodiment of the present invention, the threshold voltage increases from about 2.5 V to about 3.0 V (increase of about 0.5 V) when the write voltage increases from 11 V to 13 V. That is, compared to the conventional non-volatile memory device, an examplary embodiment of the present invention has a less change of the threshold voltage according to the write voltage.

According to an examplary embodiment of the present invention, a non-volatile memory device can store two bits by assigning data bits of ‘00’, ‘01’, ‘10’, and ‘11’ to one memory cell. According to an examplary embodiment of the present invention, a non-volatile memory device can store a plurality of data bits using the quantum confinement film 66 with the quantum confinement effect. Thus, according to an examplary embodiment of the present invention, more than two bits of data can be stored in one memory cell.

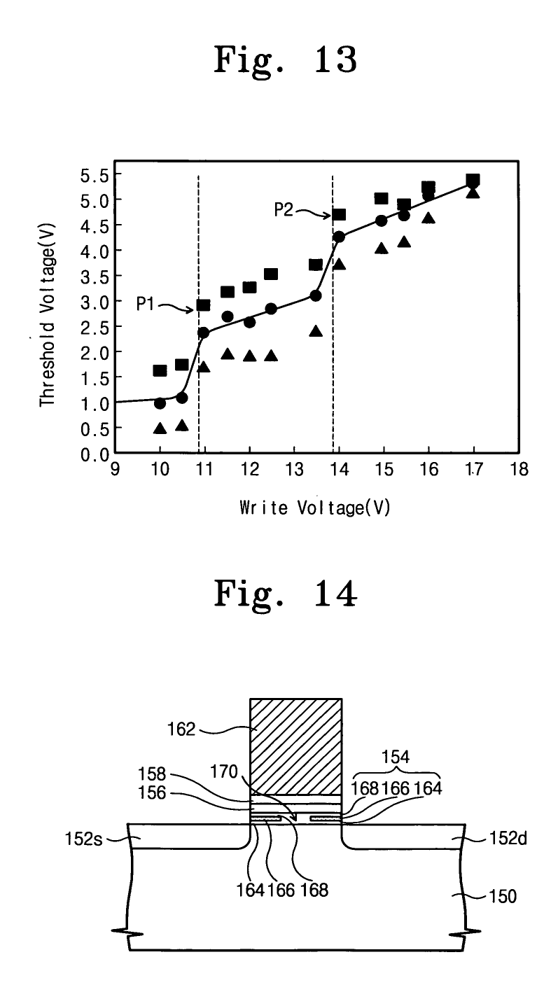

FIGS. 14 to 18 illustrate memory cell structures in which more than two bits of data can be stored according to an examplary embodiment of the present invention.

FIG. 14 is a cross-sectional view of a non-volatile memory device according to an examplary embodiment of the present invention.

Referring to FIG. 14, a source region 152s and a drain region 152d are formed on a semiconductor substrate 150, and a charge storage film comprising a plurality of films are formed on a channel region between the source region 152s and the drain region 152d. A gate electrode 162 is formed on the charge storage film. The charge storage film includes a tunnel insulating film 154, a charge trapping film 156, and a blocking insulating film 158. The tunnel insulating film 154 includes the quantum confinement film 166 having a quantum confinement effect. The tunnel insulating film 154 includes the quantum confinement film 166 interposed between a bottom tunnel insulating film 164 and a top tunnel insulating film 168. The quantum confinement film 166 is formed adjacent to the source region 152s and the drain region 152d. The quantum confinement film 166 adjacent to the source region 152s and the quantum confinement film 166 adjacent to the drain region 152d are spaced apart from each other. Accordingly, a connected portion 170 where the bottom tunnel insulating film 164 is connected to the top tunnel insulating film 168 is formed on a center surface of the channel region. The quantum confinement films 166 adjacent to the source region 152s and the drain region 152d, respectively, are spaced apart by the connected portion 170. Since the tunneling of a charge occurs in the tunnel insulating film 154 during the write operation or the erase operation, the quantum confinement film 166 may be a material with a potential barrier lower than the bottom tunnel insulating film 164 and the top tunnel insulating film 168.

In the non-volatile memory device, the writing operation through a hot carrier injection around the channel region adjacent to the source region 152s can be performed, and the writing operation through a hot carrier injection around the channel region adjacent to the drain region 152d can be performed. In the writing operation through the hot carrier injection, when electrons are not injected around the channel region adjacent to the source region 152s and the drain region 152d, and electrons are injected into the charge trap insulating film 156 around a center portion of the channel, the distribution of electrons injected into the charge trap insulating film 156 widens. Therefore, an identification of the stored information becomes difficult and an erase failure can occur.

Since a barrier of the tunnel insulating film 154 including the quantum confinement film 166 is thin, electrons can be Fowler-Nordheim (FN) tunneled in an energy state lower than that of the hot carrier injection. Accordingly, the confinement film 166 is not formed on a center of the channel to prevent the electrons from being injected into the charge trap insulating film 156 through the tunnel insulating film 154 in the center of the channel.

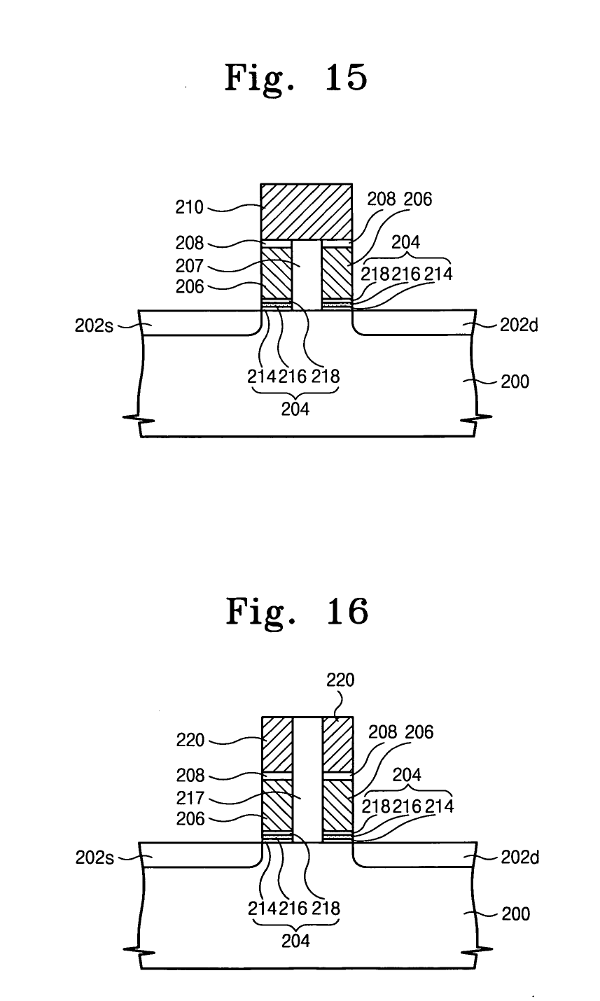

FIG. 15 is a cross-sectional view of a non-volatile memory device according to an examplary embodiment of the present invention.

Referring to FIG. 15, the non-volatile memory device includes a source region 202s and a drain region 202d formed on a semiconductor substrate 200, and a tunnel insulating film 204 comprising a bottom tunnel insulating film 214, a quantum confinement film 216, and a top tunnel insulating film 218 on a channel region between the source region 202s and the drain region 202d.

The tunnel insulating film 204 is formed adjacent to the source region 202s and the drain region 202d. The tunnel insulating film 204 adjacent to the source region 202s and the tunnel insulating film 204 adjacent to the drain region 202d are spaced apart from each other. The tunnel insulating film 204 includes the quantum confinement film 216 interposed between the bottom tunnel insulating film 214 and the top tunnel insulating film 218.

Each floating gate 206 is formed on the tunnel insulating films 204. The floating gate 206 is divided and spaced apart by the blocking insulating film 207. The blocking insulating film 207 is interposed between the floating gates 206 and the tunnel insulating films 204. The blocking insulating film 207 is formed on the center surface of the channel region. The quantum confinement film 216 adjacent to the source region 202s and the quantum confinement film 216 adjacent to the drain region 202d are divided and spaced apart by the blocking insulating film 207. The blocking insulating film 207 is formed on the center surface of the channel region and can separate the quantum confinement films 216. The bottom tunnel insulating film 214 can be connected to the top tunnel insulating film 218. Each gate interlayer dielectric film 208 is formed on the floating gates 206, and the control gate electrode 210 is formed on the floating gates 206.

The gate interlayer dielectric film 208 may comprise, for example, a silicon oxide film, a silicon nitride film, and a silicone oxide film. In an examplary embodiment of the present invention, the gate interlayer dielectric film 208 can be a single insulating film with a high dielectric constant and a low leakage current.

Similar to the charge trap type non-volatile memory device, data can be written by the hot carrier injection on the channel region around the source region 202s and the drain region 202d. Accordingly, data of four bits having two bits in each floating gate 206 can be stored in one memory cell.

FIG. 16 is a sectional view of a non-volatile memory device according to an examplary embodiment of the present invention.

Referring to FIG. 16, a control gate electrode 220 is formed on each floating gate 206. The blocking insulating film 217 is interposed between the floating gates 206 and the control gate electrodes 220.

A voltage can be applied to each of the control gate electrodes 220 separately or simultaneously. In an examplary embodiment of the present invention, the floating gates 206 are separated, and the quantum confinement film 216 is not formed on the center surface of the channel region.

FIG. 17 is a cross-sectional view of a non-volatile memory device according to an examplary embodiment of the present invention.

Referring to FIG. 17, the tunnel insulating film 204 is a single body layer, and the floating gate 206 is divided into two and separated from each other. Although the tunneling of a charge may occur through the tunnel insulating film 204 in the center of the channel region, a write failure and an erase failure do not occur since the blocking insulating film 227 is formed on the center surface of the channel region and the floating gate 206 is divided into two. The non-volatile memory device according to an examplary embodiment of the present invention includes a source region 202s and a drain region 202d formed on a semiconductor substrate 200, and a tunnel insulating film 204 including a bottom tunnel insulating film 214, a quantum confinement film 216, and a top tunnel insulating film 218 on the channel region between the source region 202s and the drain region 202d.

Each floating gate 206 is formed on the tunnel insulating films 204. The floating gates 206 are spaced apart by the blocking insulating film 227. Accordingly, the blocking insulating film 227 is formed on the center surface of the channel region. The each gate interlayer dielectric film 208 is formed on the floating gates 206, and the control gate electrode 210 is formed on the floating gates 206. In the non-volatile memory device according to an examplary embodiment of the present invention, data is written by the hot carrier injection in the channel region around the source region 202s and the drain region 202d. Accordingly, data of four bits having two bits in each floating gate 206 can be stored in one memory cell.

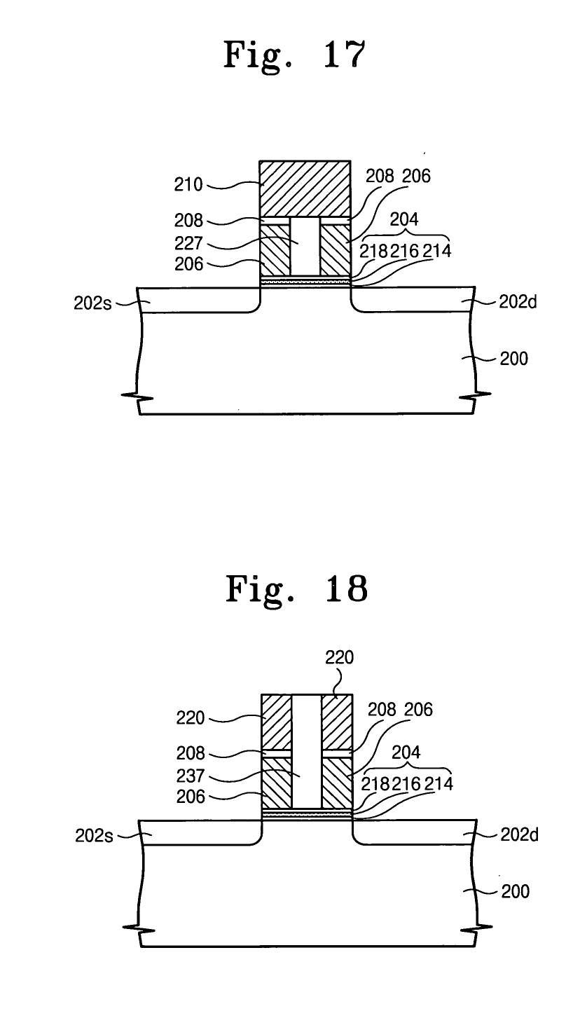

FIG. 18 is a cross-sectional view of an examplary embodiment of the present invention.

Referring to FIG. 18, each control gate electrode 220 is formed on the floating gates 206, and the blocking insulating film 237 is interposed between the floating gates 206 and the control gate electrodes 220.

According to an examplary embodiment of the present invention, the quantum confinement film is interposed between the tunnel insulating films, and a tunneling current through the tunnel insulating film increases in a step shape when a voltage applied to the gate electrode increases. Therefore, an examplary embodiment of the present invention can provide a multi-bit storageable non-volatile memory device reducing the distribution of the threshold voltage and having a wide verify window between data bits.

The quantum confinement film can be divided to prevent the tunneling of a charge through the tunnel insulating film on the center of the channel region when hot carriers are injected. An information storage region of the source region and the drain region can be divided to prevent the write failure and the erase failure.

The write voltage in relation to the threshold voltage can have a step-shaped curve according to an examplary embodiment of the present invention. Accordingly, although a voltage applied to the tunnel insulating film is changed, the distribution of the threshold voltage can be substantially small. The threshold voltage is small, and a threshold voltage difference between and at the stable intervals is large. Therefore, a verify window of the data is wide and a maintenance characteristic improves.

Although examplary embodiments have been described with reference to the accompanying drawings, it is to be understood that the present invention is not limited to these precise embodiments but various changes and modifications can be made by one skilled in the art without departing from the spirit and scope of the present invention. All such changes and modifications are intended to be included within the scope of the invention as defined by the appended claims.

What is claimed is:

1. A non-volatile memory device comprising:
a channel region defined between a source region and a drain region;
a charge storage film disposed on the channel region to store a charge; and
a tunnel insulating film interposed between the channel region and the charge storage film to tunnel the charge, the tunnel insulating film having a quantum confinement film.

2. The non-volatile memory device of claim 1, wherein the tunnel insulating film further comprises a bottom tunnel insulating film and a top tunnel insulating film formed on the bottom tunnel insulating film, and the quantum confinement film is interposed between the bottom tunnel insulating film and the top tunnel insulating film.

3. The non-volatile memory device of claim 2, wherein the quantum confinement film has a potential barrier lower than that of the top tunnel insulating film and the bottom tunnel insulating film.

4. The non-volatile memory device of claim 3, wherein the quantum confinement film comprises a semiconductor nano film with a discontinuous conduction band.

5. The non-volatile memory device of claim 1, wherein the charge storage film is a floating gate.

6. The non-volatile memory device of claim 1, wherein the charge storage film is a charge trap insulating film.

7. A non-volatile memory device comprising:
a source region and a drain region formed on a semiconductor substrate;
a tunnel insulating film formed on a channel region between the source region and the drain region;
a charge trap insulating film formed on the tunnel insulating film;
a blocking insulating film formed on the charge trap insulating film; and
a gate electrode formed on the blocking insulating film, wherein the tunnel insulating film includes a bottom tunnel insulating film, a quantum confinement film, and a top tunnel insulating film.

8. The non-volatile memory device of claim 7, wherein the quantum confinement film includes a potential barrier lower than that of the top tunnel insulating film and the bottom tunnel insulating film.

9. The non-volatile memory device of claim 8, wherein the quantum confinement film comprises a semiconductor nano film.

10. The non-volatile memory device of claim 8, wherein the quantum confinement film includes a discontinuous conduction band.

11. The non-volatile memory device of claim 7, wherein a conduction band of the tunnel insulating film includes a potential well structure with respect to electrons.

12. The non-volatile memory device of claim 7, wherein a valence band of the tunnel insulating film includes a potential well structure with respect to holes.

13. The non-volatile memory device of claim 7, wherein the quantum confinement film is divided on the center surface of the channel region to include a portion adjacent to the source region and a portion adjacent to the drain region.

14. The non-volatile memory device of claim 13, wherein the quantum confinement film includes a potential barrier lower than that of the top tunnel insulating film and the bottom tunnel insulating film.

15. The non-volatile memory device of claim 14, wherein the quantum confinement film comprises a semiconductor nano film.

16. The non-volatile memory device of claim 14, wherein the quantum confinement film includes a discontinuous conduction band.

17. The non-volatile memory device of claim 13, wherein a conduction band of the tunnel insulating film includes a potential well structure with respect to electrons.

18. The non-volatile memory device of claim 13, wherein a valence band of the tunnel insulating film includes a potential well structure with respect to holes.

19. A non-volatile memory device comprising:
a source region and a drain region formed on a semiconductor substrate;
a tunnel insulating film formed on a channel region between the source region and the drain region;
a floating gate formed on the tunnel insulating film;
a gate interlayer dielectric film formed on the floating gate; and
a control gate electrode formed on the gate interlayer dielectric film, wherein the tunnel insulating film includes a bottom tunnel insulating film, a quantum confinement film, and a top tunnel insulating film.

20. The non-volatile memory device of claim 19, wherein the quantum confinement film includes a potential barrier lower than that of the top tunnel insulating film and the bottom tunnel insulating film.

21. The non-volatile memory device of claim 20, wherein the quantum confinement film comprises a semiconductor nano film.

22. The non-volatile memory device of claim 20, wherein the quantum confinement film includes a discontinuous conduction band.

23. The non-volatile memory device of claim 19, wherein a conduction band of the tunnel insulating film includes a potential well structure with respect to electrons.

24. The non-volatile memory device of claim 19, wherein a valence band of the tunnel insulating film includes a potential well structure with respect to holes.

25. The non-volatile memory device of claim 19, wherein the floating gate is divided on the center surface of the channel region to include a portion adjacent to the source region and a potion adjacent to the drain region.

26. The non-volatile memory device of claim 19, wherein the quantum confinement film includes a potential barrier lower than that of the top tunnel insulating film and the bottom tunnel insulating film.

27. The non-volatile memory device of claim 19, wherein the quantum confinement film comprises a semiconductor nano film.

28. The non-volatile memory device of claim 19, wherein the quantum confinement film includes a discontinuous conduction band.

29. The non-volatile memory device of claim 19, wherein a conduction band of the tunnel insulating film includes a potential well structure with respect to electrons.

30. The non-volatile memory device of claim 19, wherein a valence band of the tunnel insulating film includes a potential well structure with respect to holes.

31. The non-volatile memory device of claim 19, wherein the quantum confinement film is divided to include a portion adjacent to the source region and a portion adjacent to the drain region.

32. The non-volatile memory device of claim 31, wherein the control gate electrode is formed on the floating gate, and the control gate electrode is divided into two.

33. The non-volatile memory device of claim 31, further comprising a blocking insulating film dividing the floating gate into two, wherein the blocking insulating film divides the tunnel insulating film and the control gate electrodes into two parts.

34. The non-volatile memory device of claim 25, wherein the control gate electrode is formed on the floating gate, and the control gate electrode is divided into two and spaced apart from each other.

35. The non-volatile memory device of claim 31, further comprising a blocking insulating film dividing the floating gate into two, wherein the blocking insulating film divides the control gate electrode into two parts.
